(19) United States
(12) Patent Application Publication
(10) Pub. No.: US 2013/0233807 A1
(43) Pub. Date: Sep. 12, 2013

(54) MICROREACTORS FOR SEPARATION OF HETEROGENEOUS LIQUIDS

(71) Applicant: Timothy Patrick Boyle, Loftus (AU)

(72) Inventor: Timothy Patrick Boyle, Loftus (AU)

(73) Assignee: EMPIRE TECHNOLOGY DEVELOPMENT LLC, Wilmington, DE (US)

(21) Appl. No.: 13/578,475

(22) PCT Filed: Mar. 6, 2012
(86) PCT No.: PCT/US12/27886

§ 371 Date: Aug. 10, 2012

(51) Int. Cl. B01D 17/028; B23P 17/00; B23C 3/00; B81B 1/00

(52) U.S. Cl. 210/748.02; 210/513; 210/257.1; 210/251; 210/802; 29/558; 409/131

(57) ABSTRACT

A microreactor for separating heterogeneous liquids including a series or baffles and passageways is disclosed herein along with a methods for using such microreactors, and methods for manufacturing such microreactors.

### SUMMARY

Various embodiments are directed to microreactors for separating heterogeneous liquids, the Microreactor including an inlet port, a plurality of baffles disposed within, the microreactor defining a series of vertical, channels that are operably connected to the inlet port in which adjacent baffles include at least one passageway on alternating upper and lower surfaces of the microreactor that operably connects adjacent vertical channels, at least one lower outlet port on a lower surface of the microreactor and downstream of the inlet port, and at least one upper outlet port on an upper surface of the microreactor and downstream of the inlet port.

Other embodiments are directed to methods for separating a heterogeneous liquid having an aqueous component and an organic component, the method including the steps of creating a flow of the heterogeneous liquid through a microreactor including a series of vertical channels in which adjacent vertical channels are operably connected by passageways on alternating upper and lower surfaces of the microreactor, collecting the organic component in an upper portion of each vertical channel, as the heterogeneous liquid flows through the microreactor, removing the organic component from at least one upper outlet port disposed on an upper surface of the microreactor, and removing the aqueous component from at least one lower outlet port disposed on a lower surface of the microreactor.

Still other embodiments are directed to methods for manufacturing a microreactor, the methods including the steps of providing an inert material having an upper surface and a lower surface, machining the inert material to provide a plurality of baffles defining a series of vertical channels in which adjacent baffles include at least one passageway operably connecting adjacent vertical channels on alternating upper and lower surfaces of the inert material, machining at least one inlet port into the inert material, the inlet port being operably connected to at least one vertical, channel, machining at least one upper outlet port on an upper surface of the inert material, the upper outlet port being operably connected to at least one vertical channel, and machining at least one lower outlet port on an lower surface of the inert, material, the lower outlet port being operably connected to at least one vertical channel.

### BRIEF DESCRIPTION OF THE FIGURES

FIG. 1 depicts an illustrative example of a microreactor for separating heterogeneous liquids,

FIG. 2 shows illustrative examples of microreactors having a reservoir for a heterogeneous liquid either contained within the microreactor body FIG. 2A or as an external reservoir FIG. 2B.

FIG. 3 shows illustrative examples of microreactors having an upper reservoir and a lower reservoir either contained within the microreactor body FIG. 3A or as external reservoirs FIG. 3B.

### DETAILED DESCRIPTION

In the following detailed description, reference is made to the accompanying drawings, which form a part hereof. In the drawings, similar symbols typically identify similar components unless context dictates otherwise. The illustrative embodiments described in the detailed description, drawings, and claims are not meant to be limiting. Other embodiments may be utilized and other changes may be made, without departing from the spirit or scope of the subject matter presented herein. It will be readily understood that the aspects of the present disclosure, as generally described herein and illustrated in the Figures, can be arranged, substituted, combined, separated, and designed in a wide variety of different configurations, all of which are explicitly contemplated herein.

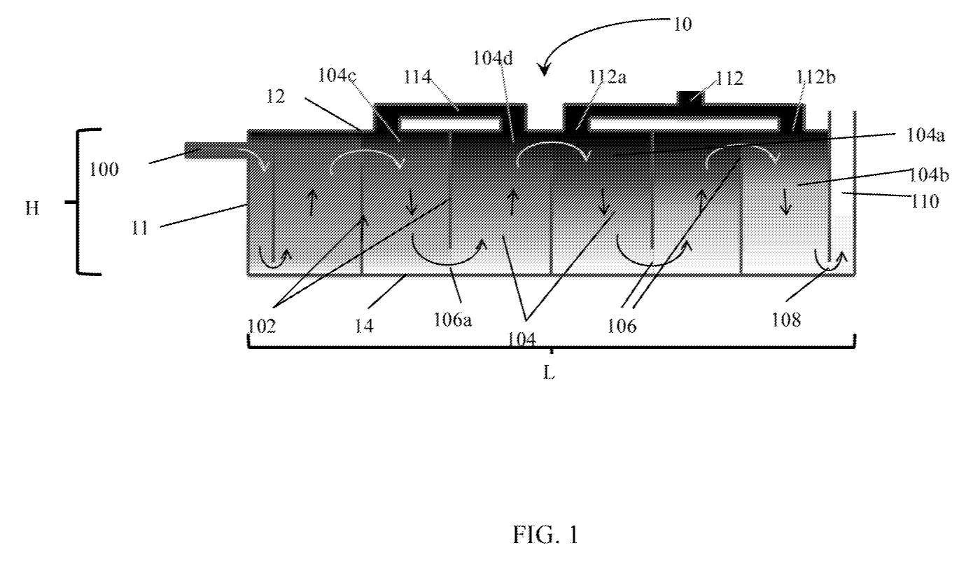

Embodiments are generally directed to a microreactor 10 for separation of heterogeneous liquids as exemplified in FIG. 1. Such microreactors 10 may include a microreactor body 11, an inlet port 100, baffles 102 disposed within the microreactor body 11 that define a series of vertical channels 104 that are operably connected to the inlet port 100 and provide a path for the flow of a heterogeneous liquid (arrows). In some embodiments, the baffles 102 may be arranged to provide passageways 106 on alternating upper surface 12 and lower surface 14 of the microreactor body 11 that operably connect adjacent vertical channels 104. In certain embodiments, the microreactor 10 may include a lower outlet port 108 on a lower surface 14 of the microreactor body 11 that is downstream of the inlet port 100, and in some embodiments, the lower outlet port 108 may include an outlet port extender 110 configured to carry a dense portion of the separated liquids away from microreactor 10. In further embodiments, the microreactor 10 may include an upper outlet port 112 on an upper surface 12 of the microreactor body 11 and downstream of the inlet port 100, and in some embodiments, the upper outlet port 112 may allow for the transport of a less dense portion of the separated liquids away from the .microreactor 10. In particular embodiments, the upper outlet port may include more than one upper outlet port two or more upper outlet ports 112a and 112b associated with adjacent vertical channels 104a and 104b. In some embodiments, the microreactor 10 may include one or more connectors 114 on an upper surface 12 of the microreactor body 11 operably connecting adjacent vertical channels 104c and 104d, in which the passageway 106a connecting the vertical channels 104c and 104d is provided on a lower surface 14 of the micro-reactor body 11. In other embodiments, the microreactor 10 may include one or more secondary passageways that may be provided on an upper surface of the baffles operably connecting adjacent vertical channels (not depicted).

In certain embodiments, the microreactor 10 may include a hydrophobic material. In some embodiments, the hydrophobic material may be incorporated into the upper portion 12 of the microreactor body 11 and an upper portion of the baffles 102 and may provide an additional means by which an aqueous portion of the heterogeneous mixture is compelled toward the lower surface 14 of the microreactor body 11. The hydrophobic material may be incorporated into the entire upper portion of the microreactor body 11 or the hydrophobic material may be incorporated into one or more vertical, channels 104. In some embodiments, the hydrophobic material may be a coating applied to the baffles 102 or upper portion of the microreactor body 11, and in other embodiments, the hydrophobic material may be an engineering polymer that makes up the structural components of the microreactor body 11 and/or the baffles 102. In still other embodiments, the hydrophobic material may be incorporated into or coated onto the entire microreactor body 11 and baffles 102 or a hydrophobic engineering polymer may be used to create the entire microreactor body 11 and/or baffles 102. In embodiments in which a hydrophobic material is applied to an upper surface 12 of the microreactor body 11, the hydrophobic material may be provided on up to about 95%, up to about 85%, up to about 75%, up to about 60%, up to about 50%, up to about 30%, up to about 25%, up to about 15%, or at least 10% or any range therebetween of the upper surface 12 of the microreactor body 11 and baffles 102 and therefore the upper portion of each vertical channel 104, For example, in embodiments m which the microreactor 10 includes vertical channels 104 having a height of about 50 mm, up to about 37.5 mm or the upper portion of the vertical channel 104 may include the hydrophobic material up to about 25 mm, up to about 12.5 mm, or at least 5 mm of the upper portion of the vertical channels 104 may include a hydrophobic material.

In further embodiments, the microreactor 10 may include a hydrophilic material. In some embodiments, the hydrophilic material may be incorporated into the lower portion of the microreactor body 11 and baffles 102 and may provide an additional means by which an aqueous portion of the heterogeneous mixture is compelled, toward the lower surface 14 of the microreactor body 11. The hydrophilic material may be incorporated into the entire lower portion of the microreactor body 11 and/or baffles 102 or the hydrophilic material may be incorporated into one or more vertical channel 104. In some embodiments, the hydrophilic material may be a coating applied to the microreactor body 11 and/or baffles 102 of the lower portion of the microreactor body 11, and in other embodiments, the hydrophilic material may be an engineering polymer that makes up the structural components of the microreactor body 11 and/or the baffles 102. In still other embodiments, the hydrophilic material may be incorporated throughout the microreactor body and baffles or a hydrophilic engineering polymer may be used to create the entire microreactor body 11 and/or baffles 102. In embodiments in which a hydrophilic material is applied to an lower portion of the microreactor body 11 and/or baffles 102, the hydrophilic material may be provided on, for example, up to about 95%, up to about 85%, up to about 75%, up to about 60%, up to about 50%, up to about 30%, up to about 25%, up to about 15%, or at least 10% or any range therebetween of the lower portion of each vertical channel 104. For example, in embodiments in which the microreactor 10 includes vertical channels 104 having height of about 50 mm, up to about 37.5 mm or the lower portion of the vertical channel 104 may include the hydrophilic material, for example, up to about 25 mm, up to about 12.5 mm, or at least 5 mm of the lower portion of the vertical channels 104 may include a hydrophilic material.

In particular embodiments, the microreactor body 11 and/or baffles 102 may include both a hydrophobic material and a hydrophilic material. For example, in some embodiments, the microreactor body 11 and/or baffles 102 may include a hydrophobic material in an upper portion of the microreactor body 11 and/or baffles 102 and a hydrophilic material in a lower portion of the microreactor body 11 and/or baffles 102. As above, in some embodiments, the hydrophobic material may be applied as a coating or a hydrophobic engineering polymer may be used to make the microreactor body 11 and/or baffles 102. In other embodiments, the microreactor body 11 and/or baffles 102 may be composed of a hydrophobic or hydrophilic engineering polymer, and a material that is not used, as the engineering polymer may be applied as a coating to an upper or lower portion of the microreactor body 11 and/or baffles 102.

The microreactors 10 of embodiments may include vertical channels 104 having any hydraulic diameter or width and length, and in microreactors 10 with two or more vertical channels 194, the vertical channels 104 may have a uniform hydraulic diameter or non-uniform hydraulic diameter. For example, in various embodiments, the vertical channels 104 may have a hydraulic diameter of about 50 μm to about 2 mm, about 75 μm to about 1.75 nun, about 100 μm to about 1.5 mm, about 125 μm to about 1.25 mm, or about 150 μm to about 1 mm. Specific examples of hydraulic diameter include about 50 μm, about 75 μm, about 100 μm, about 125 μm, about 150 μm, about 250 μm, about 500 μm, about 750 μm, about 1 mm, about 1.25 mm, about 1.5 mm, about 1.75 mm, about 2 mm, and ranges between any two of these values. In some embodiments, a first vertical channel nearest the inlet port 100 may have a larger hydraulic diameter than subsequent vertical channels which may have substantially uniform hydraulic diameters or increasingly smaller hydraulic diameters. For example, in certain embodiments, a first vertical channel may have a hydraulic diameter of from about 150 μm to about 2 mm, specifically, about 150 μm, about 250 μm, about 500 μm, about 750 μm, about 1 mm, about 1.25 mm, about 1.5 μm, about 1.75 mm, about 2 mm, and subsequent adjoining vertical channels may have a hydraulic diameter that is less than the hydraulic diameter of the first vertical channel, for example, with a hydraulic diameter of about 50 μm to about 1.5 mm, specifically, 50 μm, about 75 μm, about 100 μm, about 125 μm, about 150 μm, about 250 μm, about 500 μm, about 750 μm, about 1 mm, about 1.25 mm, about 1.5 mm. In other embodiments, the final vertical channel closest to the outlet port 108 may have a larger hydraulic diameter than preceding vertical channels. For example, in some embodiments, the first and final vertical channels may have hydraulic diameters that are substantially similar and larger than the hydraulic diameter of intervening vertical channels.

The vertical channels 164 of various embodiments may have any height. For example, in some embodiments, the height of each vertical channel 104 may be, but not limited to, about 5 mm to about 100 mm, about 10 mm to about 80 mm, or about 20 mm to about 50 mm. Specific examples of heights include about 5 mm, about 10 mm, about 20 mm, about 25 mm, about 30 mm, about 40 mm, about 50 mm, about 60 mm, about 70 mm, about 75 mm, about 80 mm, about 90 mm, about 100 mm, and ranges between any two of these values. This height may generally include the distance between the upper surface 12 of the microreactor body 11 and the lower surface 14 of the microreactor body 11 and may encompass passageways 106 and other such features contained within the vertical channels 104.

The microreactor body 11 may be sized to contain vertical channels 104 having the size described above. For example, in various embodiments the microreactor body 11 may have a height (H) of be about 3 mm to about 100 mm, about 10 to about 80 mm, or about 20 to about 50 mm, a length (L) of be about 5 mm to about 100 mm, about 10 to about 80 mm, or about 20 to about 50 mm, and a width of about be about 5 mm to about 100 mm, about 10 to about 80 mm, or about 20 to about 50 mm. In some embodiments, the dimensions may be substantially the same such that the microreactor body 11 is a cube. In other embodiments, one or more dimensions may be shorter or longer than another dimension. For example, in certain embodiments the microreactor body 11 may have a length of about 50 mm to about 100 mm and a height and width that is less than the length. In other embodiments, the height may be less than the length and the width may be less than the height. Notwithstanding the exemplary dimensions provided above, the dimensions of the microreactor body 11 described herein may be in any configuration. The optimal dimensions may be dependent on flow rate and the physical properties and miscibility of the organic phase with the aqueous phase.

The microreactors 10 of various embodiments may be manufactured from any material known in the art. For example, in some embodiments, the microreactor body 11 may be made from a polymeric material such as, but not limited to polycarbonate, polyacrylate, polyacrylonitrile, polyester, polyamide, polystyrene, polyurethane, polyepoxy, poly(acrylonitrile butadiene styrene), polyimide, polyarylate, poly(arylene ether), polyethylene, polypropylene, polyphenylene sulfide, polyvinyl ester), polyvinyl chloride, bismaleimide polymer, polyanhydride, polyether, and/or polyphenylene oxide. In certain embodiments, the microreactor body 11 may be made from an inert material such as, for example, glass, poly(methyl methacrylate), polytetrafluoroethylene, or a combination thereof. In other embodiments, the microreactor body 11 may be made from a hydrophobic or hydrophilic material.

In operation, a heterogeneous liquid may be introduced into the microreactor 10 through the inlet port 100, and hydrostatic pressure may allow the heterogeneous liquid to flow through the vertical channels 104 and through the passageways 106. While within the vertical channels 104, a denser portion of the heterogeneous liquid may be allowed to settle toward a lower surface 14 of the microreactor body 11, as indicated by the lighter colored shading in FIG. 1, while a less dense or more buoyant portion of the heterogeneous liquid, indicated by the darker colored shading in FIG. 1, may be collected toward the upper surface 14 of the microreactor 11. As the heterogeneous passes through the vertical channels 104, the less dense or more buoyant portion of the liquid may be removed, winch may increase the concentration of the more dense portion of the liquid in the microreactor 10, and the lower portion of the microreactor 10 collects the denser portion of the heterogeneous liquid in subsequent vertical channels 104 finally being removed by the outlet port 108.

In various embodiments, the heterogeneous liquid may include an aqueous

phase and an organic phase. The aqueous phase, being denser than the organic phase, may generally collect toward the lower surface 14 of the microreactor body 11 while the organic phase may be collected and removed at the upper surface 12 of the microreactor body 11. The organic phase may be removed via the upper outlet port 112 and the aqueous phase may be removed from the microreactor body 11 via the lower outlet port 108. As such, the microreactor 10 may be used to separate either an organic material that can be used in a subsequent reaction from an aqueous material that can be discarded or used in a separate reaction, or the aqueous phase may be used in a separate reaction and the organic material may be discarded.

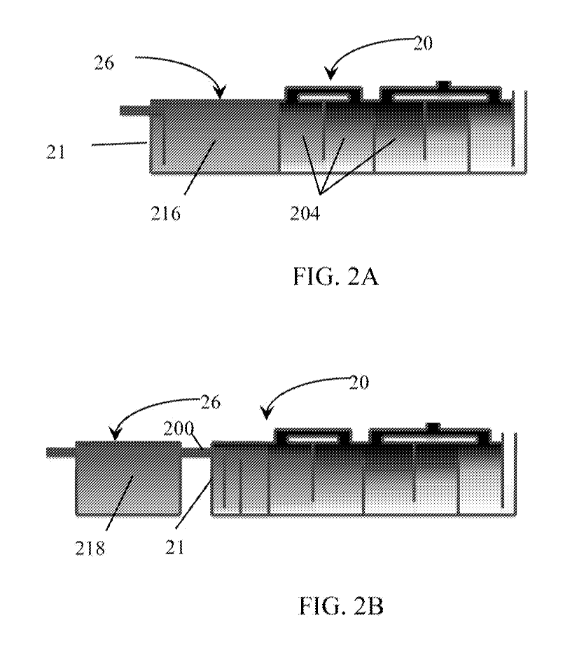

As illustrated in FIG. 2. the microreactor 20 may further include a heterogeneous liquid reservoir 26 where the heterogeneous liquid is collected before separating in the vertical channels 204. In some embodiments as illustrated in FIG. 2A, the reservoir may be incorporated into the microreactor body 21 as a first vertical channel 204 that is larger than subsequent vertical channels 204. For example, in various embodiments, the heterogeneous liquid reservoir 216 may have a vertical channel-like shape with a volume that is up to about 20% greater; up to about 30% greater, up to about 50% greater or op to about 75% greater than subsequent vertical channels 204, and in such embodiments, separation of the heterogeneous liquid may begirt in the reservoir 216. As will be understood by the skilled artisan, the maximum could be higher than 75% depending on the ratio of organic to aqueous solutions and the physical properties and miseibility of the solution.

In other embodiments as illustrated in FIG. 28, the microreactor 20 may include at least one external heterogeneous liquid reservoir 218 that is not contained within the microreactor body 21. The external heterogeneous liquid reservoir 218 may be operably connected to the inlet port 200 and may be configured to hold the heterogeneous liquid before being passed through the microreactor 20, and in embodiments, in which two or more external heterogeneous liquid reservoirs are used, each reservoir may hold the same or different heterogeneous liquids before being passed through the microreactor. In some embodiments, processing of the heterogeneous liquid may begin in the external heterogeneous liquid reservoir 218. For example, in certain embodiments, the heterogeneous liquid may be subjected to sonication in an external heterogeneous liquid reservoir 218, and in other embodiments, heterogeneous liquid may be stirred or otherwise mixed in the external heterogeneous liquid reservoir 218. The microreactor may include either an internal reservoir 216 or an external heterogeneous liquid reservoir 218, or in some embodiments, the microreactor may include both an internal reservoir 216 and an external heterogeneous liquid reservoir 218.

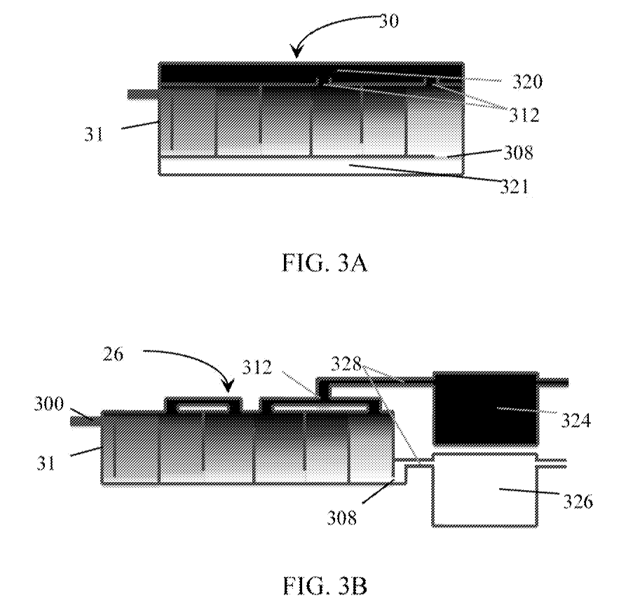

In other embodiments as illustrated in FIG. 3, the microreactor 30 may include one or more tipper reservoirs 320 for the collected less dense, more buoyant material, or organic material, and in some embodiments as illustrated in FIG. 3A, the microreactor 30 may include one or more lower reservoirs 322 for the denser or aqueous material. In certain embodiments, the microreactor 30 may include one or more upper reservoirs 320 and one or more lower reservoir 322, and at least one upper reservoir 320 and/or at least one lower reservoir 322 may be contained within the microreactor body 31 as a separate compartment associated with the upper 312 or lower outlet port 308 as illustrated in FIG. 3A. In other embodiments as illustrated FIG. 3B, an upper reservoir 324 and/or a lower reservoir 326 may be external to the microreactor body 31 and connected to the upper outlet port 312 or lower outlet port 308 using one or more conduits 328. The upper reservoir 324 and/or the lower reservoir 326 are not limited to a particular design. For example, in some embodiments, the upper reservoir 324 or the lower reservoir 326 may be a vessel such as a vial or test tube that allows for collection and transport of the separated material (not depicted), in other embodiments as illustrated in FIG. 3B, the upper reservoir 324 or lower reservoir 326 may be a vessel that is operably connected to an additional separator, a reactor, or the like to provide an in-line storage vessel within a larger device, in some embodiments, the upper outlet port 312 or the lower outlet port 308 may be operably connected to waste. For example, in particular embodiments, the upper outlet port 312 or lower outlet port 308 may be connected to a conduit that transports the separated, material to a drain or other waste receptacle where the waste material can be discarded. In other embodiments, the upper outlet port 312 or lower outlet port 308 may be operably connected to a waste vessel where the separated liquid is collected. Such waste material may be collected and held or reintroduced into a first separator or introduced into a second separator.

In further embodiments, the microreactor 30 may further include one or more conduits 328 operably connecting the inlet port 300, the lower outlet port 308, or the upper outlet, port 312 to reservoirs such as those described above, additional separators, or reactors in which the separated materials are further reacted within a larger device that is designed for the production of, for example, a particular organic material. Such conduits may generally be tubes having a diameter substantially similar to the inlet port 300 or outlet ports 312, 308.

The microreactors 10, 20, 30 of the embodiments described above may be configured to separate all or nearly all of the constituents of the heterogeneous liquid. For example, in embodiments in which the microreactor is used to separate a heterogeneous mixture including an organic phase and an aqueous phase, the microreactor may separate at least about 50% of the aqueous portion of the heterogeneous liquid from the organic portion of the heterogeneous liquid, and in other embodiments from about 50% to about 100%, about 60% to about 95% or about 75% to about 90% of the aqueous portion of the heterogeneous mixture may be removed from an organic portion using the microreactor. Specific examples of percent removal include about 50%, about 60%, about 70%, about 75%, about 80%, about 90%, about 95%, about 99%, in an ideal embodiment 100%, or ranges between any two of these values.

In still other embodiments, additional microreactors may be provided in a sequence. For example, in some embodiments, a heterogeneous mixture may be introduced into a first microreactor that separates at least about 50% of the aqueous portion of the mixture from the organic portion of the mixture, and the organic phase may be introduced into a second microreactor that separates at least about 50% of the remaining aqueous portion of the heterogeneous mixture from the organic portion of the heterogeneous mixture. Thus, as the heterogeneous mixture continues through sequential microreactors, the aqueous portion of the mixture may be further separated arid the organic separation may be further isolated and/or purified.

Particular embodiments are directed to devices including the microreactor described above, and in such embodiments, the devices may include one or more additional components. For example, in some embodiments, the microreactor may include a degassing system to remove gasses from, the heterogeneous mixture that may interfere with the separation, and in other embodiments, the microreactor may include a venting system to remove gasses that build up in the microreactor body during the separation process. In still other embodiments, the microreactor may include a sonicating system directed toward the microreactor and positioned, to sonicate the microreactor or a portion of a microreactor, and in further embodiments, the microreactor may include at least one or both of a heating or cooling system.

The microreactors of various embodiments may be configured to allow for continuous or intermittent flow of heterogeneous liquid continuous flow of heterogeneous liquid through the microreactor. In other embodiments, the microreactor may be configured for individual use. In some embodiments, mechanical pumping or pressure may be applied to the heterogeneous liquid to control the flow of the heterogeneous liquid through the microreactor. For example, mechanical pumps such as, for example, piston pumps, peristaltic pumps, syringe pumps, pneumatic pumps, diaphragm pumps, and the like, can be used to build up and maintain the flow of heterogeneous liquid through the microreactor. in other embodiments, a hydrostatic system that may include a one or more reservoir for the heterogeneous liquids such as those described above that allow the heterogeneous liquid to pass through the microreactor by their own pressure.

In such embodiments, any transfer rate through the microreactor may be used, and in particular embodiments, the flow of heterogeneous liquid may be maintained at about 0.005 ml/min to about 40 ml/min. In other embodiments, the transfer rate through microreactor may be, but not limited to, about 0.01 ml/min to about 30 ml/min or about 0.1 ml/min to about 25 ml/min. Specific examples of .flow rate include about 0.01 ml/min, about 0.1 ml/min, about 1 ml/min, about 5 ml/min, about 10 ml/min, about 20 ml/min, about 30 ml/min, about 40 ml/min, and ranges between any two of these values.

Embodiments are also directed to methods for separating heterogeneous liquids, and particular embodiments are directed to methods for separating heterogeneous liquids having an aqueous component and an organic component. In some embodiments, such methods may include creating a flow of the heterogeneous liquid through a microreactor that includes a series of vertical channels in which adjacent vertical channels are operably connected by passageways on alternating upper and lower surfaces of the microreactor. As discussed above, creating a flow of heterogeneous liquids may be effectuated by hydrostatic pressure, or a mechanical pump may be used to induce flow of the heterogeneous liquid through the microreactor. The microreactors of various embodiments can be used to separate phases after any reaction and can be designed, to separate heterogeneous liquids in scalable processes.

In some embodiments, the methods may further include collecting an organic component in an upper portion, of each vertical, channel as the heterogeneous liquid flows through the microreactor and removing the organic component from at least one upper outlet port disposed on an upper surface of the microreactor. In particular embodiments, the organic component may be collected, in a reservoir or vessel after being removed from the microreactor, and some embodiments include storing the organic component for subsequent use. In other embodiments, the method may include transporting the organic component to an additional reactor and inducing flow of the organic component in the additional reactor. The second reactor may be a second microreactor for separating heterogeneous liquids, or a reactor configured to carry out a reaction with the organic component. In such embodiments, the steps of creating a flow of heterogeneous liquid and collecting the organic component may be carried out contemporaneously,

Still other embodiments may include removing the aqueous component from at least one lower outlet port disposed on a lower surface of the microreactor. As with the organic component, the aqueous component may be collected in a reservoir or vessel after being removed from the microreactor, and in some embodiments the aqueous component may be stored for subsequent use. In other embodiments, the method may include transporting the aqueous component to an additional reactor and inducing flow of the aqueous component in the additional reactor. The second reactor may be a second microreactor for separating heterogeneous liquids, or a reactor configured to carry out a reaction with the aqueous component. In such embodiments, creating a flow of heterogeneous liquid and collecting the aqueous component may be carried out contemporaneously, and in certain embodiments, creating a flow, collecting the organic component, and collecting the aqueous component may be carried out contemporaneously.

Further embodiments of methods include sonicating the heterogeneous liquid. The sonicating may be carried out within the microreactor by sonicating the entire apparatus, or individual components of the microreactor such as, for example, a reservoir associated with the inlet port or a first, second, or third vertical channel or combination thereof. In other embodiments, the heterogeneous liquid may be sonicated in a conduit positioned to deliver the heterogeneous liquid to the microreactor.

In still further embodiments, methods may include degassing the heterogeneous liquid. As with sonicating, degassing may be carried out with the microreactor within the entire apparatus or within particular individual components of the microreactor or within a reservoir associated with the inlet port of the microreactor. Degassing can be carried out by any means known in the art. For example, degassing may be accomplished by applying a vacuum to the microreactor or a portion thereof. In other embodiments, the method may include venting gasses that may build up within the microreactor and affect the flow of heterogeneous liquid through the microreactor.

Additional embodiments are directed to methods for manufacturing a microreactor including providing an inert material having an upper surface and a lower surface and machining the inert material to provide a plurality of baffles defining a series of vertical channels, in which the adjacent baffles include at least one passageway operably connecting adjacent vertical channels on alternating upper and lower surfaces. In some embodiments, the methods may further include machining at least one inlet port into (he inert material, the inlet port being operably connected to at least one vertical, channel. In other embodiments, the method may include machining at least one upper outlet port on an upper surface of the inert material, the upper outlet port being operably connected to at least one vertical channel and/or machining at least one lower outlet port on a lower surface of the inert material, the lower outlet port being operably connected to at least one vertical channel. In such embodiments, machining may be carried out by computer numerical control (CNC) machining or milling, and in various embodiments, the inert material may be, but not limited to, glass, poly(methyl methacrylate), or polytetrafluoroethylene.

In some embodiments, the microreactor may be manufactured in two or more pieces that may be attached and sealed to one another to make the completed microreactor. For example, in particular embodiments, the methods may include machining a first half of the microreactor and machining a corresponding second half of the microreactor. The method may further include joining the first and second halves of the microreactor and, in some embodiments, sealing the joined first and second halves of the microreactor to create the complete microreactor. In various embodiments, joining may be accomplished using machined snaps or screws, and in certain embodiments, joining and sealing may be simultaneously accomplished by applying an adhesive and/or sealant to a least one half of the halves of the microreactor. As will be appreciated by the person of ordinary skill in the art, an adhesive and/or sealant may be applied in any embodiment including those in which the first and second halves are joined by snaps or screws. In further embodiments, a hydrophobic material, a hydrophilic material, or both may be applied to a portion of the microreactor before the halves are joined.

In still other embodiments, methods for manufacturing may include the steps of attaching additional components such as, for example, conduits, reservoirs, vessels, additional microreactors, other reactors, or combinations thereof to the microreactor. As above, the methods may include joining the additional components and sealing the additional components to the microreactor using, for example, an adhesive or sealant.

### EXAMPLES

### Example 1

### Microreactor Manufacture:

A polymethyl methacrylate microreactor will be formed by photoetching using glass slides as outer substrates. A layer of silicon dioxide will be formed on the first glass slide by first cleaning the slide to remove organic and inorganic contaminants from the surface of the slide using the RCA process. Briefly, the slide will he soaked in deionized water, and then cleaned with a 1:1:5 solution of ammonium hydroxide (NH₄OH): hydrogen peroxide (H₂O₂): water (H₂O) at 75° C. or 80° C. for 10 minutes. The slide will then be transferred into a deionized water bath. This treatment will result in the formation of a thin silicon dioxide layer (about 10 Angstrom) on the surface, along with a certain degree of metallic contamination by immersing the slide in a 1:50 solution of hydrogen fluoride (HF): H₂O at 25° C. and then a 1:1:6 solution of hydrochloric acid (HCl): H₂O₂: H₂O at 75° C. or 80° C. to remove oxide and metallic (ionic) contaminants.

A solution of polymethyl methacrylate (PMMA) consisting of 8 parts of PMMA and 92 parts of toluene by weight will be deposited to a depth of 2 mm onto a 35 mm×50 mm section of the glass slide. A mold of such dimensions can be used to ensure uniformity with the required dimensions. The substrate will be heated to a temperature of about 170° C. for a period of 40 minutes to remove arty residue of toluene in the PMMA and to enhance the adhesion of the layer of PMMA to the surface of the layer of glass slide. The temperature of heating was chosen to be less than the temperature at which significant decomposition of polymer occurs.

An azide photoresist material specifically will be deposited on the surface of the layer of PMMA. The aside resist will include a novalac resin that is soluble in an alkaline solvent or developer, a photoactive compound such as dizaonaphthoqninone that inhibits solubility in the novalac resin in the alkaline solvent until it is activated by radiation, a suitable solvent for the resist such as cellosolve acetate, and minor ingredients such as film forming additives, dyes, and plasticizers. The slide will be spun at a speed of about 6000 rpm for about 15 seconds to form an azide layer having a thickness of about 0.3 μm on the PMMA layer. The slide will then be heated to a temperature of about 95° C. for a period of 10 minutes to remove any residue of the solvent.

The azide layer will then be exposed to a pattern of radiation having wavelengths in the range of about 405 nm to about 436 nm to form a pattern of vertical channels and passageways, openings, and connectors, such as those illustrated in FIG. 1, formed on exposed or irradiated portions of the azide layer. Unexposed portions in the azide layer will provide baffles and. boundary walls. The exposed portions of the azide layer will be removed by immersing the slide a suitable developer, such as Shipley MF-351 developer, to form a pattern of removed portions and retained portions in the azide layer.

The slide will next he irradiated with deep ultraviolet radiation having a wavelength of from about 200 nm to about 230 nm that will be blocked by the unremoved portions of the azide layer and passed through the removed portions of the aside allowing the UV radiation to impinge on the PMMA layer. The PMMA is sensitive to this band of radiation, and scission or depolymerization of the PMMA material will occur upon irradiation. The azide and PMMA layer will be immersed in a solution of 2 parts acetone and 1 part of isopropanol for 20 seconds to remove the exposed portion of the PMMA and aside layers.

A second glass slide will be cleaned and a layer of silicon dioxide will be formed on the surface of the slide using the RCA process as described above. The PMMA of the first slide will be exposed briefly to UV radiation within the range cited above to form a thin layer of depolymerized PMMA on the surface of the PMMA layer. The second slide will be placed on top of the PMMA layer and should bind to the PMMA layer creating a second outer wall for the microreactor and providing a complete microreactor. Glass or PMMA tubes will then be attached to openings in the microreactor at inlet ports and upper and lower outlet ports for delivery and removal of materials from the microreactor.

### Example 2

### Separation of a Heterogeneous Liquid:

A heterogeneous mixture of equal parts water and hexane will be prepared and thoroughly mixed by shaking. The heterogeneous mixture produced will be applied to the microreactor produced as described above through the inlet port. The aqueous component will be extracted from the microreactor through the lower outlet port and hexane will be extracted from the microreactor through the upper outlet port. After collecting the aqueous component, the aqueous component will be thoroughly mixed, and the amount of hexane remaining in the aqueous material removed from the microreactor will be determined by mass spectroscopy.

After rinsing with DI water, the aqueous material from the first separation will then be re-applied to the microreactor. The aqueous component will be collected, from the lower outlet and hexane will be collected from the upper outlet. Mass spectroscopy will again be used to determine the amount of hexane remaining in the aqueous material This procedure will be continued 5-10 times. The results of mass spectroscopy will be plotted to determine the effectiveness of the microreactor for separating heterogeneous liquids with each pass.

Similar heterogeneous mixtures having more or less hexane, e.g., 1.5:1, 0.5:1, etc. hexane to water, will he prepared and passed through the microreactor to determine its effectiveness with heterogeneous mixtures of different consistencies. Additionally, heterogeneous mixtures having different constituents, e.g, ethanol and hexane, water and acetic acid, etc., will be prepared and passed through the microreactor. The data is expected to show that separation is effective (at least 50% reduction in the organic component from the heterogeneous mixture) after a first pass through the microreactor, and up to 100% of the organic component can be removed after three passes through the microreactor.

One skilled in the art will appreciate that, for this and other processes and methods disclosed herein, the functions performed, in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fell within the scope of the appended claims. The present disclosure is to be limited only by the terms of the appended claims, along with the full scope of equivalents to which such claims are entitled. It is to be understood that this disclosure is not limited to particular methods, reagents, compounds, compositions or biological systems, which can, of course, vary. It is also to be understood that the terminology used herein is for the purpose of describing particular embodiments only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general terms used herein, and especially in the appended claims (e.g., bodies of the appended claims) are generally intended as “open” terms (e.g., the term “including” should be interpreted as “including but not limited to,” the term “having” should be interpreted as “having at least,”the term “includes” should be interpreted as “includes but is not limited to,” etc.). It will be further understood, by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim, recitations. However, the use of such phrases should not be construed to imply that the introduction, of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled, in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc,” is used, in general such a construction is intended in the sense of one having skill in the art would understand the convention (e.g., “a system having at least one of A, B, and C” would include but not be limited to systems that have A alone, B alone, C alone, A and B together, A and C together, B and C together, and/or A, B, and C together, etc). In those instances where a convention analogous to “at least one of A, B, or C, etc.” is used, in general, such a construction is intended in the sense of one having skill, in the art would understand the convention (e.g., “a system having at least one of A, B, or C” would include but not be limited to systems that have A alone, B alone, C alone, A and B together, A and C together, B and C together, and/or A, B, and C together, etc). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art, all language such as “up to,” “at least,” and the like include the number recited and refer to ranges which can be subsequently broken down into subranges, as discussed above. Finally, as will be understood by one skilled in the art, a range includes each individual, member. Thus, for example, a group having 1-3 cells refers to groups having 1, 2, or 3 cells. Similarly, a group having 1-5 ceils refers to groups having 1, 2, 3, 4, or 5 cells, and so forth.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. A microreactor for separation of heterogeneous liquids, the microreactor comprising:
an inlet port;
a plurality of baffles disposed within the microreactor and defining a series of vertical channels that are operably connected to the inlet port, wherein adjacent baffles comprise at least one passageway on alternating upper and lower surfaces of the microreactor and operably connecting adjacent vertical channels;
at least one lower outlet port on a lower surface of the microreactor and downstream of the inlet port; and
at least one upper outlet port on an upper surface of the microreactor and downstream of the inlet port.

2. The microreactor of claim 1, further comprising a reservoir for the heterogeneous liquid adjacent and operably connected to the inlet port.

3. The microreactor of claim 1, further comprising at least one connector on an upper surface of the microreactor operably connecting adjacent vertical channels.

4. The microreactor of claim 1, further comprising one or more secondary passageways defined on an upper surface of the baffles operably connecting adjacent vertical channels.

5. The microreactor of claim 1, wherein the at least one upper outlet port comprises two or more upper outlet ports operably connected to adjacent vertical channels.

6. The microreactor of claim 1, further comprising a conduit operably connected to the inlet port and connecting the inlet port to a reactor.

7. The microreactor of claim 1, further comprising a conduit operably connected to at least one upper outlet port and connecting the at least one upper outlet port to a reactor, a reservoir, or a waste receptacle.

8-9. (canceled)

10. The microreactor of claim 1, further comprising a conduit operably connected to at least one lower outlet port and connecting the at least one lower outlet port to a reactor, a reservoir, or a waste receptacle.

11-12. (canceled)

13. The microreactor of claim 1, further comprising a sonicator positioned to sonicate the microreactor or a portion thereof.

14. (canceled)

15. The microreactor of claim 1, wherein the microreactor is configured to allow the aqueous component to be removed from the microreactor through the at least one lower outlet port.

16. The microreactor of claim 1, wherein the microreactor is configured to all the allow organic components to be removed from the microreactor through the at least one upper outlet port.

17. The microreactor of claim 1, further comprising a hydrophobic material on an upper portion of at least one vertical channel.

18. The microreactor of claim 1, wherein the microreactor and baffles or portions thereof comprise a hydrophobic engineering polymer.

19. The microreactor of claim 1, further comprising a hydrophilic material on a lower portion of at least one vertical channel.

20. The microreactor of claim 1, wherein the microreactor and baffles or portions thereof comprise hydrophilic engineering polymer.

21. The microreactor of claim 1, further comprising a degassing system.

22. The microreactor of claim 1, further comprising at least one venting mechanism.

23. A method for separating a heterogeneous liquid having an aqueous component and an organic component, the method comprising:
creating a flow of the heterogeneous liquid through a microreactor comprising a series of vertical channels, wherein adjacent vertical channels are operably connected by passageways on alternating upper and lower surfaces of the microreactor;
collecting the organic component in an upper portion of each vertical channel as the heterogeneous liquid flows through the microreactor;
removing the organic component from at least one upper outlet port disposed on an upper surface of the microreactor; and
removing the aqueous component from at least one lower outlet port disposed on a lower surface of the microreactor.

24. The method of claim 23, further comprising sonicating the microreactor.

25. The method of claim 23, further comprising degassing the heterogeneous liquid.

26. The method of claim 23, wherein creating a flow and collecting the organic component occur contemporaneously.

27. The method of claim 23, further comprising venting gasses.

28. A method for manufacturing a microreactor, the method comprising:
providing an inert material having an upper surface and a lower surface;
machining the inert material to provide a plurality of baffles defining a series of vertical channels, wherein adjacent baffles comprise at least one passageway operably connecting adjacent vertical channels on alternating upper and lower surfaces of the inert material; and
machining at least one inlet port into the inert material, the inlet port being operably connected to at least one vertical channel;
machining at least one upper outlet port on an upper surface of the inert material, the upper outlet port being operably connected to at least one vertical channel; and
machining at least one lower outlet port on an lower surface of the inert material, the lower outlet port being operably connected to at least one vertical channel.

29. The method of claim 27, wherein machining comprises computer numerical control (CNC) machining or milling.

30. The method of claim 27, wherein the inert material comprises glass, poly(methyl methacrylate), or polytetrafluoroethylene.
